(19) United States
(12) Patent Application Publication
(10) Pub. No.: US 2023/0245926 A1
(43) Pub. Date: Aug. 3, 2023

(54) Method for Manufacturing Semiconductor Device

(71) Applicant: Nippon Telegraph and Telephone Corporation, Tokyo (JP)

(72) Inventors: Takuya Tsutsumi, Musashino-shi, Tokyo (JP); Hideaki Matsuzaki, Musashino-shi, Tokyo (JP)

(21) Appl. No.: 18/002,525

(22) PCT Filed: Jun. 24, 2020
(86) PCT No.: PCT/JP2020/024783

§ 371 Date: Dec. 20, 2022

(51) Int. Cl. H01L 21/78; H01L 21/768; H01L 23/48

(52) U.S. Cl. CPC H01L 21/78; H01L 21/76898; H01L 23/481; H01L 21/3043

(57) ABSTRACT

A groove is formed around a chip region of a principal surface of a substrate by an etching process or cutting with a dicing blade (a second step). Next, the substrate is thinned from a back-surface side of the substrate to cause a bottom of the groove to reach a backside of the substrate to serve as a space, thus cutting out a portion that is to be a chip of the chip region (a third step).

### TECHNICAL FIELD

The present invention relates to a method of manufacturing a semiconductor device including cutting a chip, in which a semiconductor device is formed, out of a substrate.

### BACKGROUND ART

An electromagnetic wave frequency band of 0.3 to 3.0 THz, or millimeter waves, exhibit properties that potentially provide possibilities for creation of unprecedented new applications such as high-speed wireless communication at over 100 Gb/s, non-destructive internal inspection by three-dimensional imaging, and component analysis by using electromagnetic wave absorption. To implement a millimeter-wave-based application, an electronic device that provides the application is required to exhibit more favorable high-frequency characteristics. A transistor including, as a material, a compound semiconductor having as a material property, a particularly high electron mobility is usually used as an electronic device having favorable high-frequency characteristics.

However, in the field of ICs for terahertz, a new scheme allowing for lossless propagation of a superhigh-frequency signal is necessary in addition to speed-up of a transistor. The most serious problem with such transmission is that a high-frequency signal propagating through a wiring on a semiconductor substrate generates radiation/excitation to a substrate with a high permittivity, destabilizing an IC operation.

The following two measures are effective in reducing such destabilization of an IC operation. Measures 1 include thinning a semiconductor substrate to block excitation in a substrate-thickness direction. Measures 2 is forming ground vias (through wirings) penetrating a semiconductor substrate at narrow intervals to block excitation in a substrate-plane direction.

By virtue of the above-described measures, excitation of a high-frequency signal in a semiconductor substrate can be blocked and, consequently, stabilization of an operation of an IC for millimeter waves can be achieved.

A conventional IC for millimeter waves is designed to be stabilized in operation by thinning a substrate and forming a substrate-through wiring as described in Non-Patent Literature 1. Thinning the substrate contributes to blocking excitation in the substrate-thickness direction according to Measures 1 described above. In addition, forming the substrate-through wiring contributes to blocking excitation in the substrate-plane direction according to Measures 2.

Description will be made below on a structure of a semiconductor device and a brief outline of a manufacturing method thereof according to Non-Patent Literature 1. First, an integrated circuit is formed on a front surface of a semiconductor substrate, the integrated circuit including an active element, such as a transistor, or a passive element, such as a resistor or a capacitor, and a circuit component such as a front-surface wiring for connecting the elements or a power-source line/pad for supplying voltage/power. Next, a glass substrate is mounted on the front surface of the semiconductor substrate with an adhesive agent in between, thereby supporting the semiconductor substrate such that a back surface of the semiconductor substrate can be machined even after the substrate is thinned. Next, the semiconductor substrate is subjected to mechanical grinding from the back surface thereof to be thinned until it has a desired thickness.

Next, patterning of an etching mask is performed using a photosensitive resin and a substrate-through via is formed by reactive ion etching. Next, a substrate-through wiring is formed by applying metal plating to an inside of the substrate-through via, thereby electrically connecting the front-surface wiring and a back-surface wiring. Subsequently, the semiconductor substrate is subjected to dicing from the back surface thereof into a chip and transferred onto a film, and then the glass substrate is peeled.

By virtue of the above-described series of steps, the thinning of the substrate and the formation of the substrate-through wiring are achieved with a high yield and stabilization of an operation of an IC for millimeter waves can be achieved by blocking excitation of a millimeter wave in the semiconductor substrate.

### CITATION LIST

### Patent Literature

### Non-Patent Literature

Non-Patent Literature 1: T. Tsutsumi et al., “Feasibility Study of Wafer-Level Backside Process for InP-Based ICs”, IEEE Transactions on Electron Devices, vol. 66, no. 9, pp. 3771-3776, 2019.

### SUMMARY OF THE INVENTION

### Technical Problem

However, a technology described in Non-Patent Literature 1 is disadvantageous in terms of an influence of a stress during thinning of a semiconductor substrate. This limitation has a large influence even on a structure of the semiconductor device at completion of steps.

According to a conventional technology, after a front surface of a semiconductor substrate is bonded to a glass substrate with an adhesive agent, mechanical grinding is applied from a back surface thereof to thin the semiconductor substrate over the entire substrate surface. In a case where the semiconductor substrate is thinned until it has a thickness of several tens μm in order to reduce excitation of a millimeter wave within the substrate, the thickness of the thinned substrate becomes comparable to or less than a thickness of the adhesive agent. In this case, a residual stress within a layer of the adhesive agent causes the thinned semiconductor substrate to deform with a variation in height in a plane of the substrate. As a result, a finished chip thickness considerably deviates depending on an in-plane position. The deviation of the chip thickness causes an error in size during a later module-mounting step, which leads to a deterioration in characteristics such as an increase in connection loss due to cavity resonance within a module or occurrence of positional misalignment.

A variation in chip thickness, of course, means a variation in depth in a plane among the above-described substrate-through vias. Accordingly, a step for forming vias also requires a margin more than necessary, which results in an influence on an accuracy of a substrate-through wiring and, consequently, on an increase in density. Therefore, it has not been easy to manufacture a semiconductor device capable of performing a stable high-frequency operation.

The present invention is made to solve a problem as described above and an object thereof is to provide a method of manufacturing a semiconductor device capable of performing a stable high-frequency operation.

### Means for Solving the Problem

A method of manufacturing a semiconductor device according to the present invention includes: a first step of forming a chip region in which a semiconductor element is formed on a principal surface of a substrate: a second step of forming a groove around the chip region on the principal surface of the substrate; and a third step of cutting out a portion that is to be a chip of the chip region by thinning the substrate from a back-surface side of the substrate to cause the groove to reach a backside of the substrate.

### Effects of the Invention

As described hereinabove, according to the present invention, a groove is formed in a substrate at a spot serving as a scribe line and then the substrate is thinned from a back surface thereof to cause a bottom of the groove to be reached, which makes it possible to provide a method of manufacturing a semiconductor device capable of a stable high-frequency operation.

### BRIEF DESCRIPTION OF DRAWINGS

FIG. 1A is a cross-sectional view for explaining a method of manufacturing a semiconductor device according to Embodiment 1 of the present invention, illustrating a state of a semiconductor device in an intermediate step.

FIG. 1B is a cross-sectional view for explaining the method of manufacturing a semiconductor device according to Embodiment 1 of the present invention, illustrating the state of the semiconductor device in an intermediate step.

FIG. 1C is a cross-sectional view for explaining the method of manufacturing a semiconductor device according to Embodiment 1 of the present invention, illustrating the state of the semiconductor device in an intermediate step.

FIG. 1D is a cross-sectional view for explaining the method of manufacturing a semiconductor device according to Embodiment 1 of the present invention, illustrating the state of the semiconductor device in an intermediate step.

FIG. 1E is a cross-sectional view for explaining the method of manufacturing a semiconductor device according to Embodiment 1 of the present invention, illustrating the state of the semiconductor device in an intermediate step.

FIG. 1F is a cross-sectional view for explaining the method of manufacturing a semiconductor device according to Embodiment 1 of the present invention, illustrating the state of the semiconductor device in an intermediate step.

FIG. 1G is a cross-sectional view for explaining the method of manufacturing a semiconductor device according to Embodiment 1 of the present invention, illustrating the state of the semiconductor device in an intermediate step.

FIG. 1H is a cross-sectional view for explaining the method of manufacturing a semiconductor device according to Embodiment 1 of the present invention, illustrating the state of the semiconductor device in an intermediate step.

FIG. 2A is a cross-sectional view for explaining a method of manufacturing a semiconductor device according to Embodiment 2 of the present invention, illustrating a state of a semiconductor device in an intermediate step.

FIG. 2B is a cross-sectional view for explaining the method of manufacturing a semiconductor device according to Embodiment 2 of the present invention, illustrating the state of the semiconductor device in an intermediate step.

FIG. 2C is a cross-sectional view for explaining the method of manufacturing a semiconductor device according to Embodiment 2 of the present invention, illustrating the state of the semiconductor device in an intermediate step.

FIG. 2D is a cross-sectional view for explaining the method of manufacturing a semiconductor device according to Embodiment 2 of the present invention, illustrating the state of the semiconductor device in an intermediate step.

FIG. 2E is a cross-sectional view for explaining the method of manufacturing a semiconductor device according to Embodiment 2 of the present invention, illustrating the state of the semiconductor device in an intermediate step.

FIG. 2F is a cross-sectional view for explaining the method of manufacturing a semiconductor device according to Embodiment 2 of the present invention, illustrating the state of the semiconductor device in an intermediate step.

FIG. 2G is a cross-sectional view for explaining the method of manufacturing a semiconductor device according to Embodiment 2 of the present invention, illustrating the state of the semiconductor device in an intermediate step.

FIG. 2H is a cross-sectional view for explaining the method of manufacturing a semiconductor device according to Embodiment 2 of the present invention, illustrating the state of the semiconductor device in an intermediate step.

FIG. 2I is a cross-sectional view for explaining the method of manufacturing a semiconductor device according to Embodiment 2 of the present invention, illustrating the state of the semiconductor device in an intermediate step.

FIG. 2J is a cross-sectional view for explaining the method of manufacturing a semiconductor device according to Embodiment 2 of the present invention, illustrating the state of the semiconductor device in an intermediate step.

FIG. 3 is a plan view illustrating a shape of a chip 101a obtainable by the method of manufacturing a semiconductor device according to the embodiment of the present invention.

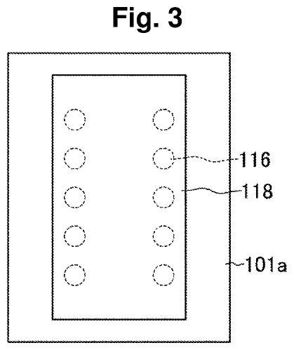

FIG. 4 is a plan view illustrating a shape of a chip 101b obtainable by the method of manufacturing a semiconductor device according to the embodiment of the present invention.

### DESCRIPTION OF EMBODIMENTS

Description will be made below on a method of manufacturing a semiconductor device according to an embodiment of the present invention.

### Embodiment 1

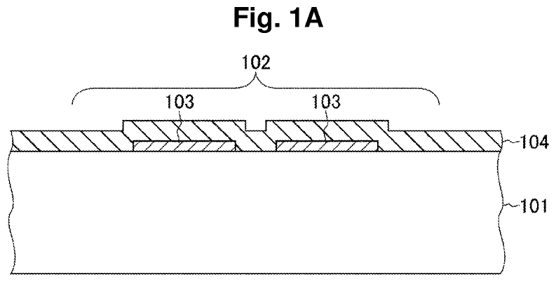

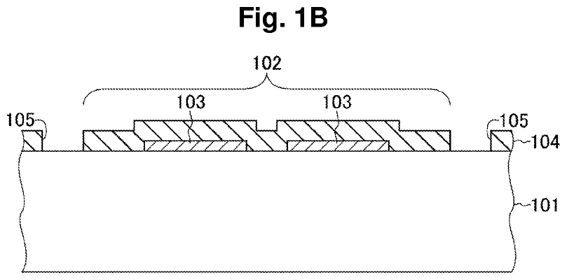

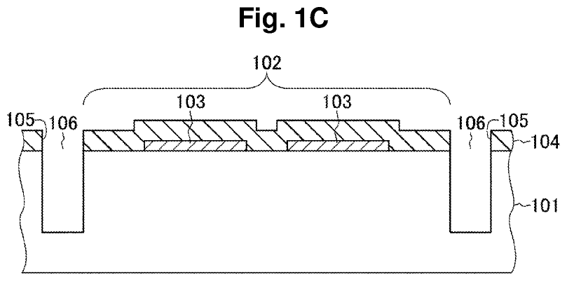

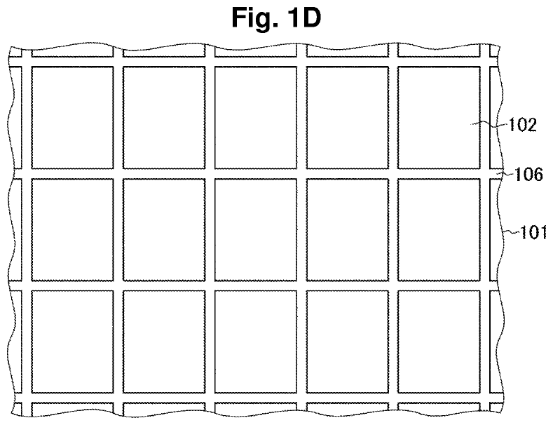

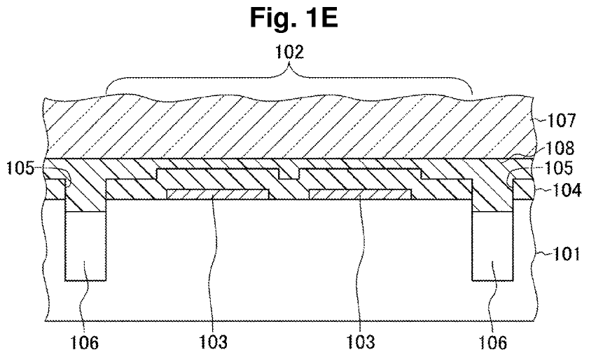

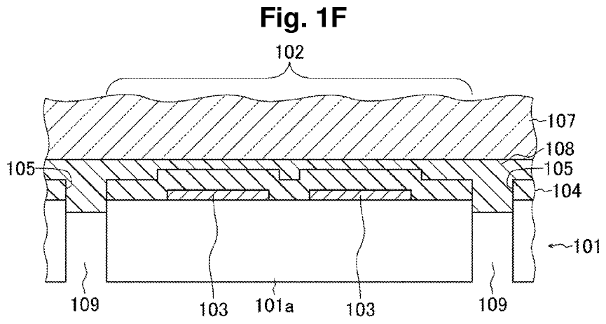

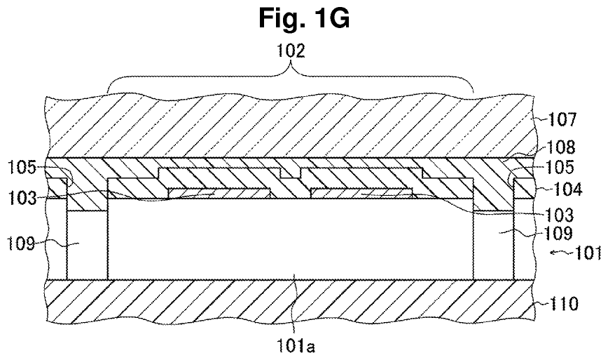

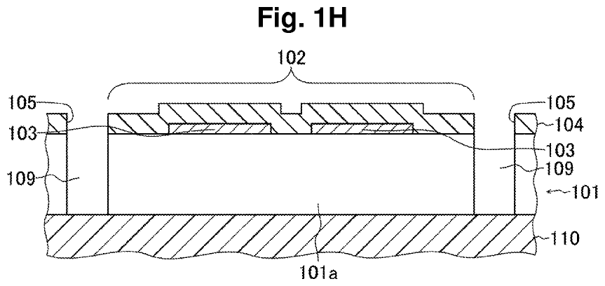

First of all, description will be made on a method of manufacturing a semiconductor device according to Embodiment 1 of the present invention with reference to FIG. 1A to FIG. 1H. It should be noted that FIG. 1A, FIG. 1B, FIG. 1C, FIG. 1E, FIG. 1F, FIG. 1G, and FIG. 1H illustrate a region of a single chip region 102.

First, the chip region 102 in which a semiconductor element (not illustrated) is formed on a principal surface of a substrate 101 is formed as illustrated in FIG. 1A (a first step). The substrate 101 includes, for example, a semiconductor such as InP, GaAs, Si, or GaN. The element is, for example, an active element such as a transistor or a passive element such as a resistor or a capacitor.

In addition, a front-surface wiring 103 for connecting these elements is formed on the principal surface of the substrate 101. In addition, an integrated circuit where circuit components such as a power-source line/pad for supplying voltage/power are integrated is formed on the principal surface of the substrate 101. In addition, a passivation film 104 is formed on the principal surface of the substrate 101, covering the above-described elements, the front-surface wiring 103, and the integrated circuit. The passivation film 104 includes a silicon oxide film, a silicon nitride film, an organic resin, or a composite deposited film thereof.

Next, an opening 105 is formed in the passivation film 104 around the chip region 102 as illustrated in FIG. 1B. For example, the passivation film 104 is patterned by known lithography technology, and etching technology, or the like, thereby forming the opening 105. First, with a photoresist applied onto the passivation film 104 to form a resist layer, a spot corresponding to the opening 105 is subjected to lithographic exposure by a photolithography technology to form a latent image and then a latent image spot is dissolved and removed by image development, thereby forming a resist pattern with an opening formed at the spot corresponding to the opening 105.

Next, with use of the resist pattern as a mask, the passivation film 104 is selectively etched by dry etching with a gas such as SF₆, CF₄, or C₂F₆, thereby forming the opening 105. It should be noted that in a case where the passivation film 104 includes a photosensitive resin, the opening 105 can be formed in the passivation film 104 by a photolithography technology.

Next, the substrate 101 is subjected to an etching process with use of the passivation film 104 as a mask pattern, thereby forming a groove 106 around the chip region 102 on the principal surface of the substrate 101 as illustrated in FIG. 1C (a second step). The groove 106 is formed at a depth larger than a thickness of the later-described thinned substrate 101 by 10% or more. For example, in a case where the substrate 101 is thinned to have a thickness of 50 μm, the depth of the groove 106 is 55 μm. At this time, a bottom of the groove 106 does not reach a back surface of the substrate 101. The groove 106 can be formed in a lattice pattern in a plan view (FIG. 1D). The groove 106 is provided by forming a well-known scribe line deeper.

Although the groove 106 can also be formed by an etching process, the groove 106 can also be formed by cutting with a dicing blade. In a case where the groove 106 is formed by cutting with a dicing blade, the groove 106 is formed by cutting the substrate 101 from a front-surface side of the substrate 101 to a depth in a range not sufficient to completely penetrate the substrate 101. The formation of the groove 106 by the dicing method is characterized by a high throughput as compared with an etching method and no occurrence of a plasma damage or the like to the front surface. The dicing method is also characterized by a less mechanical influence on a wiring of the integrated circuit, which is formed on the principal surface of the substrate 101, and an insulation film between layers by virtue of no thermal stress occurring during plasma exposure.

Meanwhile, in a case where the groove 106 is formed by an etching process, a dry etching method and a wet etching method are also usable. For a wet etching method, the type of etchant, etching conditions, etc. are set in accordance with a material of the substrate 101. For example, in a case where the substrate 101 includes InP, the groove 106 can be formed by etching with an etchant based on a phosphoric acid, a hydrochloric acid, or an acetic acid.

In addition, in a case where a dry etching method is used to form the groove 106, HI, SiCl₄, HBr, Cl₂, and the like are usable as an etching gas in accordance with the material of the substrate 101. In addition, a reactive gas and dry etching conditions that allow for a sufficiently high etching rate of the substrate 101 relative to the passivation film 104 and formation of a subsequent side contact portion without corrosion of the front-surface wiring 103 or the like are employed.

An etching method is characterized by allowing the surroundings of a dicing spot to be less mechanically damaged as compared with a dicing method and facilitating miniaturization of a width of the groove 106 for efficient use of space. With these characteristics of a dicing method and an etching method taken into consideration, a method of forming the groove 106 is suitably selected by application.

Next, a support substrate 107 is bonded onto the principal surface of the substrate 101 where the passivation film 104, etc. are formed as illustrated in FIG. 1E. For example, the support substrate 107 is bonded to the substrate 101 by an adhesive layer 108 including an adhesive agent. The support substrate 107 may be a glass substrate, a ceramic substrate, or the like, including a material suitable in accordance with a process design concept. For example, either an application-type or film-type adhesive agent is usable as the adhesive agent providing the adhesive layer 108. In addition, the adhesive agent providing the adhesive layer 108, which is determinable on the basis of a step developed in accordance with a material of a semiconductor providing the substrate 101, may be an ultraviolet curable adhesive agent, a thermosetting adhesive agent, or the like. In addition, in a case where an adhesive agent itself is not necessary, for example, in a case where a direct support on the support substrate 107 is possible, the adhesive layer 108 can be omitted.

Next, the substrate 101 is thinned from a back-surface side of the substrate 101 to cause the bottom of the groove 106 to reach a backside of the substrate 101 to serve as a space 109 as illustrated in FIG. 1F, thus cutting out a portion that is to be a chip 101a of the chip region 102 (a third step). The substrate 101 can be thinned from the back-surface side thereof by, for example, a mechanical grinding method, chemical mechanical polishing (CMP), mechano-chemical polishing (MCP), and a combination thereof.

As long as the groove 106 is formed at a depth larger than a target thickness of the substrate 101, the groove 106 (the bottom thereof) is caused to reach the back surface of the substrate 101 to serve as the space 109 by thinning the substrate 101 until it has the target thickness, thus causing the respective portions of chip regions 102 that are to be chips 101a to be separated independently of each other. By virtue of such thinning of the substrate 101, a dicing line provided by the space 109 is formed at a spot of the groove 106 described with reference to FIG. 1D. The target thickness of the substrate 101 is set thinner than at least a thickness calculated by “(semiconductor substrate thickness)=(wavelength in vacuum corresponding to operation frequency)/(permittivity of semiconductor substrate) 0.5/4” in order to block excitation of a high-frequency signal within the substrate.

For example, in a case where an InP substrate is used to implement an IC for millimeter waves that operates at 300 GHz, a wavelength in vacuum is 1mm, approximately, and the permittivity of InP is 12.4; therefore, 1 mm/°12.4/4=0.071 mm. Accordingly, machining is performed to provide at least a thickness of 70 μm, approximately, or less.

As described above, the groove 106 is formed without completely dividing the substrate 101 during the formation of the groove 106 and, after that, the space 109 is formed by thinning the substrate 101 and separating it into the chips 101a. This makes it possible to achieve dividing into the chips 101a with a stress during the thinning reduced at an appropriate point of time.

After the substrate 101 is thinned in the above-described manner, a film for transfer 110 is boned to the back surface of the thinned substrate 101 as illustrated in FIG. 1G. Then, the support substrate 107 is removed and the adhesive layer 108 is removed, thereby causing the substrate 101 to be separated into the chips 101a on the film for transfer 110 by virtue of the space 109 as illustrated in FIG. 1H. For example, the support substrate 107 can be separated by dissolving the adhesive layer 108 in an organic solvent or the like and removing it. After the support substrate 107 is separated, for example, the film for transfer 110 is extended with the intervals between the chips 101a increased and the chips 101a are removed from the film for transfer 110.

According to Embodiment 1 described above, in thinning the substrate 101, the substrate 101 is thinned to have a thickness comparable to or less than a thickness of the adhesive layer 108, causing the groove 106 to serve as the space 109. A stress on the substrate 101 due to thinning is thus reduced at this point of time, preventing a variation in thickness within the substrate 101. As a result, thicknesses of the substrate 101 at the formed chips 101a are each prevented from deviating depending on a position in a plane of the substrate 101. As a result, according to Embodiment 1, it is possible to manufacture a semiconductor device capable of a stable high-frequency operation.

### Embodiment 2

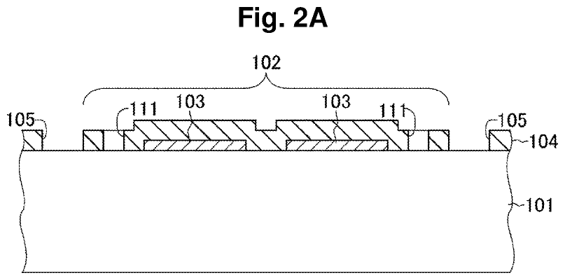

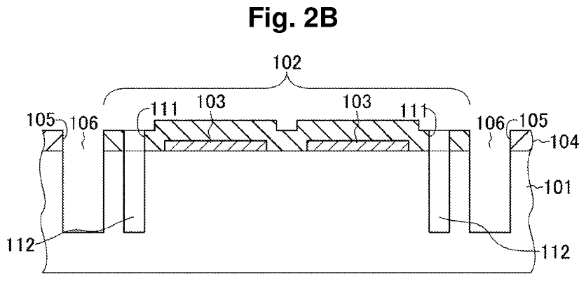

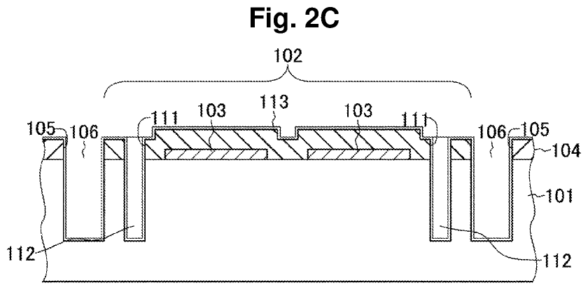

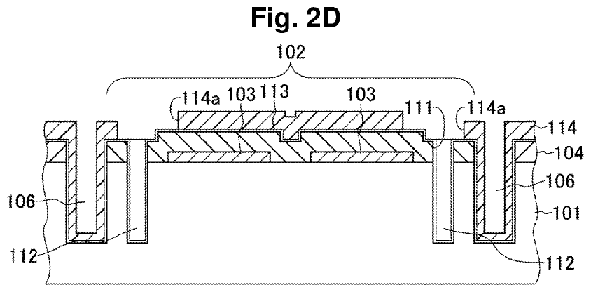

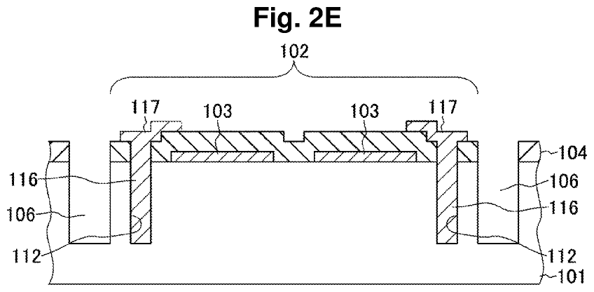

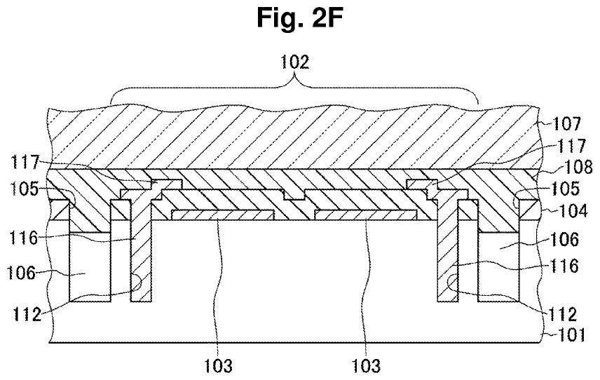

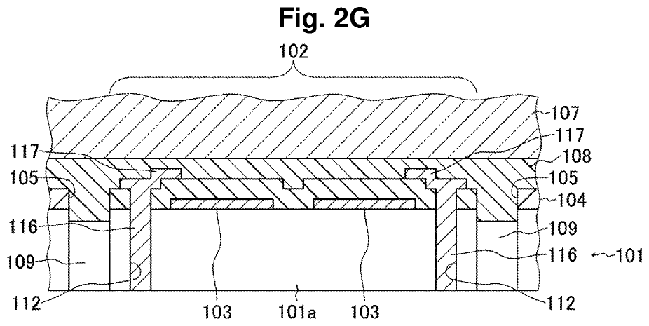

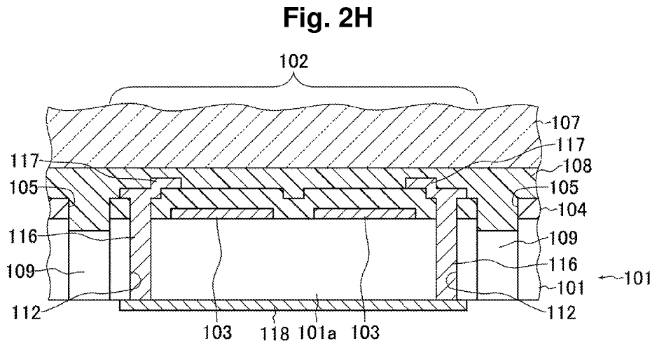

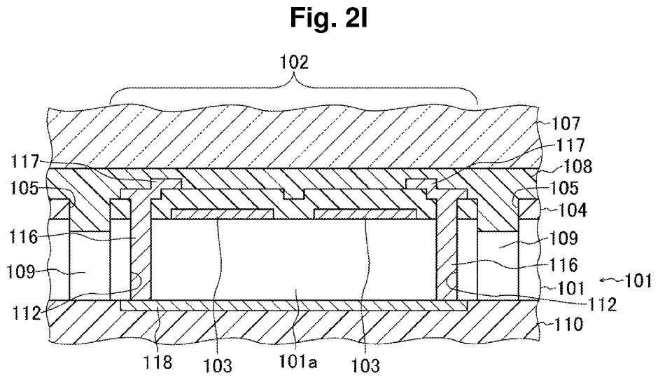

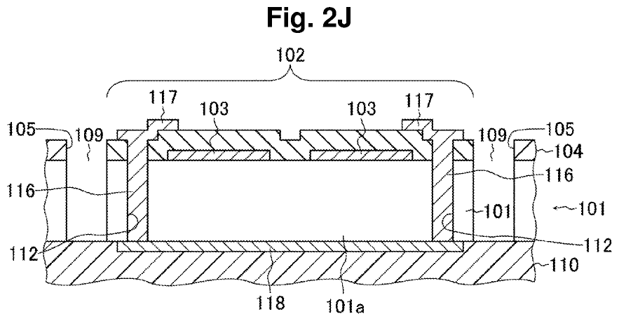

Next, description will be made on a method of manufacturing a semiconductor device according to Embodiment 2 of the present invention with reference to FIG. 2A to FIG. 2J. First, a chip region 102 in which a semiconductor element (not illustrated) is formed on a principal surface of a substrate 101 is formed (the first step) as illustrated in FIG. 2A. In addition, an integrated circuit where circuit components, such as a power-source line/pad for supplying voltage/power, including a front-surface wiring 103 are integrated is formed on the principal surface of the substrate 101. In addition, an opening 105 is formed in a passivation film 104 around the chip region 102. These are similar to those in Embodiment 1 described above and detailed descriptions thereof are omitted. In Embodiment 2, in addition to the opening 105 being formed in the passivation film 104, an opening 111 is formed in the passivation film 104 within the chip region 102. The opening 111 is usable for formation of a later-described through electrode.

Next, a groove 106 is formed around the chip region 102 on the principal surface of the substrate 101 as illustrated in FIG. 2B (the second step) and a recess 112 for forming a through electrode is formed in the substrate 101 (a fourth step). The groove 106 is formed as in Embodiment 1 described above. The recess 112 is formed to have a depth comparable to that of the groove 106 or slightly shallower than that of the groove 106. It should be noted that an example where two of the recesses 112 are formed is illustrated in this example; however, the figure illustrates a cross section and, accordingly, a number of recesses are formed in a region not illustrated. In addition, as long as a recess is formed by a known technology of manufacturing a semiconductor device, a plurality of recesses can be formed at a high density in a plan view.

Although being formed independently of each other, the groove 106 and the recess 112 can be simultaneously formed for the purpose of simplification of fixation (improvement in throughput). For example, application of an etching method makes it possible to simultaneously form them. For example, as long as a diameter of the recess 112 in a plan view is set smaller than the width of the groove 106 in a plan view, the groove 106 is formed deeper by an etching process. Such formation of the groove 106 slightly deeper than the recess 112 is advantageous in releasing a stress on the substrate 101 during subsequent thinning of the substrate 101. In thinning the substrate 101, a bottom of the groove 106 reaches the back surface of the substrate earlier than a bottom of the recess 112 to serve as a space, causing separation into chip regions 102. This makes it possible to reduce a stress on the semiconductor substrate, which is disadvantageous for thinning the substrate, and, consequently, makes it possible to reduce a planar variation in substrate thickness.

Next, a seed layer 113 is formed on the passivation film 104 even inside the groove 106 and inside the recess 112 as illustrated in FIG. 2C. For example, a metal such as Ti is deposited by a sputtering method, a vapor deposition method, or the like to form the seed layer 113. It should be noted that the seed layer 113 can also be formed only inside the recess 112 by selective metal deposition by using a resist pattern as a mask.

Next, a resist pattern 114 is formed as illustrated in FIG. 2D. For example, a photoresist is applied onto the seed layer 113 by a spin coating method or a spray coating method to form a resist layer. Subsequently, a spot corresponding to the recess 112 is subjected to lithographic exposure by a photolithography technology to form a latent image and then a latent image spot is dissolved and removed by image development, thereby forming the resist pattern 114 with an opening 114a formed at the spot corresponding to the recess 112.

Next, using the resist pattern 114 as a mask as described above, a plating process is selectively applied onto the seed layer 113 exposed in the opening 114a to form a plating film, thereby forming a through wiring 116 to form a wiring layer 117 as illustrated in FIG. 2E (a fifth step). After the through wiring 116 and the wiring layer 117 are formed, the resist pattern 114 is removed (peeled) and then the seed layer in a region other than the through wiring 116 and the wiring layer 117 is removed by a dry etching method, a wet etching method, or the like. It should be noted that the through wiring 116 can be formed to form the wiring layer 117 by depositing a metal film by a vacuum deposition method or a sputtering method instead of plating. In this case, formation of a seed layer, etc. are not necessary.

In this step, a layer of a conductor such as a metal is placed to fill or conformally formed in the recess 112, thereby forming the through wiring 116 for electrical connection to a back-surface wiring formed as described later. Prior to the formation of the through wiring 116, a wet process for removing a surface denaturation inside the recess 112 can be performed.

Gold, copper, nickel, or the like is usable as the conductor providing the through wiring 116. In these cases, an electrolytic plating method and an electroless plating method are usable. In a case where the recess 112 is tapered with a diameter thereof increased toward the front surface, a vacuum deposition method or a sputtering method can be used to deposit a metal in the recess 112 to fill it. In this case, aluminum, tungsten, titanium nitride, or the like is usable.

In addition, after the formation of the through wiring 116, a passivation film including a silicon oxide film, a silicon nitride film, an organic resin, or the like may be additionally formed. In a case where the through wiring 116 is conformally formed and the additional passivation film includes an organic resin, the recess 112, in which the through wiring 116 is conformally formed, is embedded with the organic resin, which makes it possible to improve reliability in terms of mechanical strength. It should be noted that the plurality of recesses, which are not illustrated, are formed as described above and through electrodes are also formed in these recesses in a manner similar to the above. Thus, the plurality of through electrodes are formed at a high density in a plan view.

Next, a support substrate 107 is bonded onto the principal surface of the substrate 101, on which the passivation film 104, the wiring layer 117, etc. are formed, as illustrated in FIG. 2F. For example, the support substrate 107 is bonded to the substrate 101 by an adhesive layer 108 including an adhesive agent. The bonding of the support substrate 107 is similar to that in Embodiment 1 described above.

Next, the substrate 101 is thinned from a back-surface side of the substrate 101 to cause a bottom of the recess 112 to reach a backside of the substrate 101. By virtue of the depth of the recess 112 being equal to or less than the depth of the groove 106, the bottom of the groove 106 is also caused to reach the backside of the substrate 101 while the bottom of the recess 112 is caused to reach the backside of the substrate 101. As a result, a space 109 is formed and one end of the through wiring 116 is caused to reach the backside of the substrate 101 as illustrated in FIG. 2G. By virtue of the space 109 being formed, a portion that is to be a chip 101a is cut out of the chip region 102 (the third step). The substrate 101 can be thinned from the back-surface side thereof by, for example, a mechanical grinding method, CMP, MCP, and a combination thereof.

Next, a back-surface wiring 118 that is electrically connected to the through wiring 116 is formed on the back surface of the substrate 101 as illustrated in FIG. 2H (a sixth step). Examples of the back-surface wiring 118 include a wiring for installation, a bias wiring for supplying an electric power to the integrated circuit formed on the principal surface of the substrate 101, and a high-frequency wiring. The back-surface wiring 118 can be formed by forming a resist pattern, which serves as a mask, by using an exposure apparatus capable of alignment with the already formed front-surface wiring 103, and then depositing a metal by a vacuum deposition method, a sputtering method, an electrolytic plating method, an electroless plating method, or the like. In a case where the back-surface wiring 118 is usable only for grounding, patterning is not necessary. In this case, a metal film formed all over the back surface of the substrate 101 can replace the back-surface wiring 118.

Next, a film for transfer 110 is boned to the back surface of the thinned substrate 101 as illustrated in FIG. 2I. Then, the support substrate 107 is removed and the adhesive layer 108 is removed, thereby causing the substrate 101 to be separated into the chips 101a on the film for transfer 110 by virtue of the space 109 as illustrated in FIG. 2J.

According to Embodiment 2 described above, in thinning the substrate 101, the substrate 101 is thinned to have a thickness comparable to or less than a thickness of the adhesive layer 108, causing the groove 106 to serve as the space 109. A stress on the substrate 101 due to thinning is thus reduced at this point of time, preventing a variation in thickness within the substrate 101. As a result, thicknesses of the substrate 101 at the formed chips 101a are each prevented from deviating depending on a position in a plane of the substrate 101. In addition, the high-density formation of the through wiring 116 relative to a semiconductor device can be achieved without the necessity of a considerable increase in the number of processes and a more stable high-frequency operation can be achieved. As a result, according to Embodiment 2, it is also possible to manufacture a semiconductor device capable of a stable high-frequency operation.

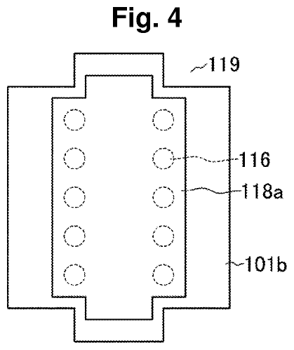

In the meantime, in a case where the groove 106 in a lattice pattern in a plan view is formed as described with reference to FIG. 1D, the chips 101a separated by the space 109 each have a rectangular shape in a plan view. For example, in forming the groove 106 using a dicing blade, the groove 106 is formed in a lattice pattern as described above. In contrast, in a case where a groove is formed by etching, a shape of the groove in a plan view is not necessarily a lattice pattern and a chip 101b having cuts 119 at four corners in a plan view can be formed with a back-surface wiring 118a being in a corresponding shape in a plan view as illustrated in FIG. 4. By virtue of such a chip shape, for example, in a case where a shape is determined in mounting the chip 101b on a module, a shape likewise having cuts is determined as a module-side fitting shape, which makes it possible to develop a subsequent mounting step such that an alignment accuracy can be improved with an unnecessary resonance in a cavity being reduced.

As described hereinabove, according to the present invention, a groove is formed in a substrate at a spot serving as a scribe line and then the substrate is thinned from a back surface thereof to cause a bottom of the groove to be reached, which makes it possible to provide a method of manufacturing a semiconductor device capable of a stable high-frequency operation.

It should be noted that the present invention is not limited to the above-described embodiments and it is obvious that a large number of modifications and a combination thereof can be carried out by those having ordinary skill in the art within the scope of the technical idea of the present invention.

### REFERENCE SIGNS LIST

101 Substrate

101a Chip

102 Chip region

103 Front-surface wiring

104 Passivation film

105 Opening

106 Groove

107 Support substrate

108 Adhesive layer

109 Space

110 Film for transfer

1. A method of manufacturing a semiconductor device, the method comprising:
forming a chip region in which a semiconductor element is formed on a principal surface of a substrate;
forming a groove around the chip region on the principal surface of the substrate; and
cutting out a portion that is to be a chip of the chip region by thinning the substrate from a back-surface side of the substrate to cause the groove to reach a backside of the substrate.

2. The method of manufacturing a semiconductor device according to claim 1, further comprising:
forming a recess for forming a through electrode in the substrate prior to cutting out a portion that is to be a chip of the chip region; and
forming the through electrode in the recess after the recess is formed prior to cutting out a portion that is to be a chip of the chip region, wherein
cutting out a portion that is to be a chip of the chip region comprises thinning the substrate from the back-surface side of the substrate to cause the through electrode to reach the backside of the substrate along with the groove.

3. The method of manufacturing a semiconductor device according to claim 2, further comprising:
forming, on the backside of the substrate, a back-surface wiring electrically connected to the through electrode after cutting out a portion that is to be a chip of the chip region.

4. The method of manufacturing a semiconductor device according to claim 1, wherein
the groove around the chip region is formed by cutting with a dicing blade.

5. The method of manufacturing a semiconductor device according to claim 1, wherein
the groove around the chip region is formed by etching.
